(19) United States
(12) Patent Application Publication
(10) Pub. No.: US 2025/0351359 A1
(43) Pub. Date: Nov. 13, 2025

(54) SEMICONDUCTOR MEMORY DEVICE AND ELECTRONIC SYSTEM INCLUDING THE SAME

(71) Applicant: Samsung Electronics Co., Ltd., Suwon-si (KR)

(72) Inventors: Jonghun YU, Suwon-si (KR); Joowon PARK, Suwon-si (KR); Chang-Sup LEE, Suwon-si (KR)

(73) Assignee: Samsung Electronics Co., Ltd., Suwon-si (KR)

(21) Appl. No.: 18/944,970

(22) Filed: Nov. 12, 2024

(30) Foreign Application Priority Data
May 10, 2024 (KR) 10-2024-0062108

(51) Int. Cl. H10B 43/35; H01L 23/00; H01L 25/18; H10B 12/00; H10B 43/40; H10B 43/50

(52) U.S. Cl. CPC H10B 43/35; H01L 24/08; H01L 25/18; H10B 12/488; H10B 12/50; H10B 43/40; H10B 43/50; H01L 2224/08145; H01L 2225/06513; H01L 2924/1436; H01L 2924/1438

(57) ABSTRACT

A semiconductor memory device including a substrate; a mold structure including a plurality of mold insulating layers and a plurality of gate electrodes alternately stacked on each other on the substrate in a first direction; a channel structure passing through the mold structure and extending in the first direction; a word line contact passing through a portion of the mold structure and extending in the first direction; and a contact spacer surrounding a side surface of the word line contact. The plurality of gate electrodes include a first gate electrode electrically connected to the word line contact. The first gate electrode includes a plate part extending in a second direction perpendicular to the first direction, and a pad part protruding from the plate part toward the word line contact. One surface of the pad part is in contact with the word line contact.

### CROSS-REFERENCE TO RELATED APPLICATION

This application claims priority to Korean Patent Application No. 10-2024-0062108, filed in the Korean Intellectual Property Office on May 10, 2024, the entire contents of which are hereby incorporated by reference.

### BACKGROUND

The present disclosure relates to semiconductor memory devices and electronic systems including the same.

There is a need for semiconductor memory devices capable of storing high-capacity data in electronic systems that require data storage. Accordingly, ways to increase data storage capacity of semiconductor memory devices are being studied. For example, as one of the methods for increasing data storage capacity of semiconductor devices, semiconductor devices which include three-dimensional arrangement of memory cells instead of two-dimensional arrangement of memory cells have been studied.

### SUMMARY

In order to solve one or more problems (e.g., the problems described above and/or other problems not explicitly described herein), some example embodiments provide a semiconductor memory device with improved electrical characteristics and reliability.

In order to solve one or more problems (e.g., the problems described above and/or other problems not explicitly described herein), some example embodiments provide an electronic system with improved electrical characteristics and reliability.

According to some example embodiments of the present disclosure, because the pad part of the gate electrode is disposed inside the contact spacer, a contact failure between the gate electrode and the word line contact can be limited and/or prevented, thereby improving reliability of the semiconductor memory device.

Some example embodiments of the present disclosure provide a semiconductor memory device including a substrate; a mold structure including a plurality of mold insulating layers and a plurality of gate electrodes alternately stacked on each other on the substrate in a first direction; a channel structure passing through the mold structure and extending in the first direction; a word line contact passing through a portion of the mold structure and extending in the first direction; and a contact spacer surrounding a side surface of the word line contact. The plurality of gate electrodes include a first gate electrode electrically connected to the word line contact. The first gate electrode includes a plate part extending in a second direction perpendicular to the first direction, and a pad part protruding from the plate part toward the word line contact. One surface of the pad part is in contact with the word line contact.

Some example embodiments of the present disclosure further provide a semiconductor memory device including a peripheral circuit structure; and a cell structure stacked on the peripheral circuit structure. The cell structure includes a substrate including a cell array region and an extension region, wherein the substrate includes a first substrate surface opposite the peripheral circuit structure and a second substrate surface opposite the first substrate surface; a mold structure including a plurality of mold insulating layers and a plurality of gate electrodes alternately stacked on each other on the first substrate surface of the substrate in a first direction; a channel structure in the cell array region, the channel structure passing through the mold structure and extending in the first direction; a word line contact in the extension region, the word line contact passing through a portion of the mold structure and extending in the first direction; and a contact spacer surrounding a side surface of the word line contact. The plurality of gate electrodes include a first gate electrode electrically connected to the word line contact. The first gate electrode includes a plate part extending in a second direction perpendicular to the first direction, and a pad part protruding from the plate part toward the word line contact. At least a portion of the pad part overlaps the contact spacer in the second direction.

Some example embodiments of the present disclosure still further provide an electronic system including a main substrate; a semiconductor memory device on the main substrate, the semiconductor memory device including a peripheral circuit structure and a cell structure stacked on the peripheral circuit structure; and a controller on the main substrate, the controller being electrically connected to the semiconductor memory device. The cell structure includes a substrate including a cell array region and an extension region, wherein the substrate includes a first surface opposite the peripheral circuit structure and a second surface opposite the first surface; a mold structure including a plurality of mold insulating layers and a plurality of gate electrodes alternately stacked on each other on the first surface of the substrate in a first direction; a channel structure in the cell array region, the channel structure passing through the mold structure and extending in the first direction; a word line contact in the extension region, the word line contact passing through a portion of the mold structure and extending in the first direction; and a contact spacer surrounding a side surface of the word line contact. The plurality of gate electrodes include a first gate electrode electrically connected to the word line contact. The first gate electrode includes a plate part extending in a second direction perpendicular to the first direction, and a pad part protruding from the plate part toward the word line contact. One surface of the pad part is in contact with the word line contact.

### BRIEF DESCRIPTION OF THE DRAWINGS

The above and other aspects and features of the present disclosure will become more apparent in view of the following detailed description of some example embodiments as made with reference to the attached drawings, in which:

FIG. 1 is a plan view provided to explain a semiconductor memory device according to some example embodiments of the inventive concepts;

FIG. 2 is a cross-sectional view taken along line A-A of FIG. 1;

FIG. 3 is a cross-sectional view taken along line B-B of FIG. 1;

FIG. 4 is an enlarged view provided to explain region Q1 of FIG. 2;

FIG. 5 is an enlarged view provided to explain region Q2 of FIG. 2;

FIGS. 6, 7, 8 and 9 are diagrams provided to explain a semiconductor memory device according to some example embodiments of the inventive concepts;

FIGS. 10, 11 and 12 are diagrams provided to explain a semiconductor memory device according to some example embodiments of the inventive concepts;

FIGS. 13 and 14 are diagrams provided to explain a semiconductor memory device according to some example embodiments of the inventive concepts;

FIGS. 15 and 16 are diagrams provided to explain a semiconductor memory device according to some example embodiments of the inventive concepts;

FIG. 17 is a diagram illustrating a semiconductor memory device according to some example embodiments of the inventive concepts;

FIGS. 18, 19, 20, 21, 22, 23 and 24 are diagrams showing intermediate stages, provided to explain a method for manufacturing a semiconductor memory device according to some example embodiments of the inventive concepts;

FIGS. 25, 26, 27, 28 and 29 are diagrams showing intermediate stages, provided to explain a method for manufacturing a semiconductor memory device according to some example embodiments of the inventive concepts;

FIG. 30 is a block diagram provided as an example to explain an electronic system according to some example embodiments of the inventive concepts;

FIG. 31 is an example perspective view illustrating an electronic system including a semiconductor memory device according to some example embodiments of the inventive concepts;

FIG. 32 is a schematic cross-sectional view taken along line V-V of FIG. 31.

### DETAILED DESCRIPTION

Hereinafter, a semiconductor memory device and a method for manufacturing the same according to some example embodiments of the present disclosure will be described in detail with reference to drawings.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

Also, for example, “at least one of A, B, and C” and similar language (e.g., “at least one selected from the group consisting of A, B, and C”) may be construed as A only, B only, C only, or any combination of two or more of A, B, and C, such as, for instance, ABC, AB, BC, and AC.

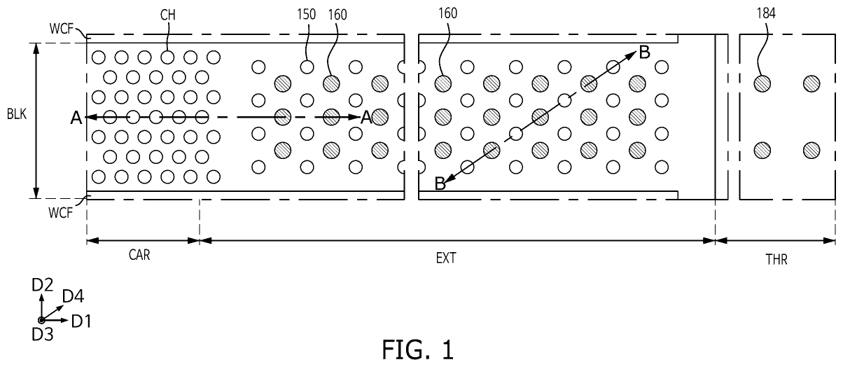

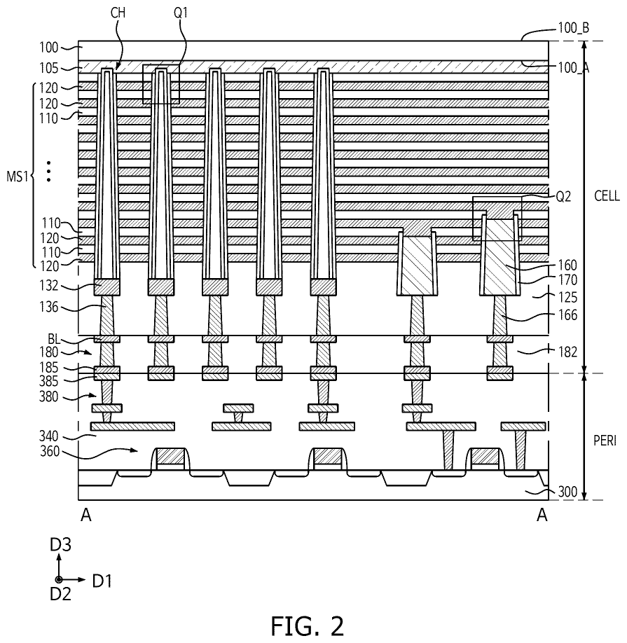

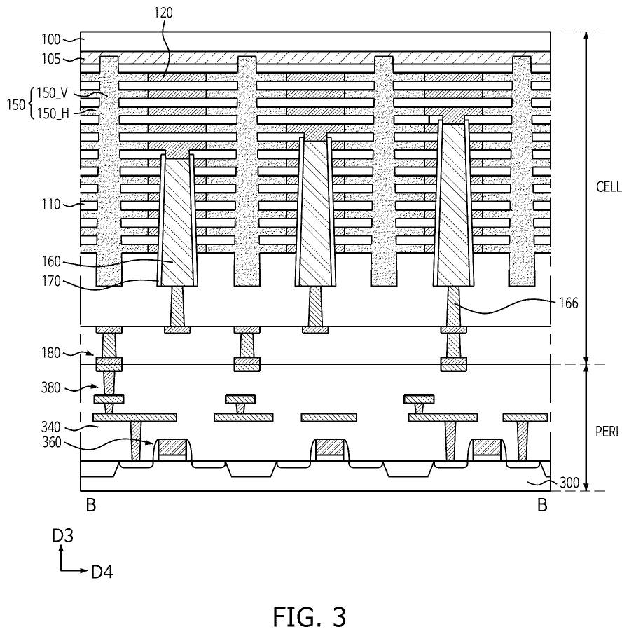

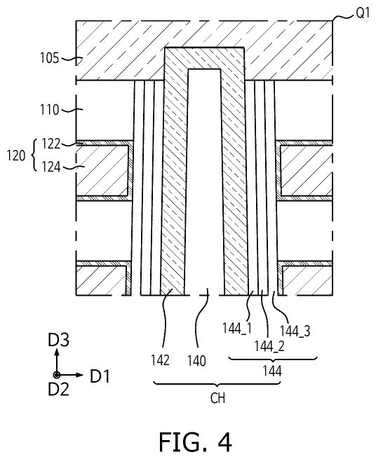

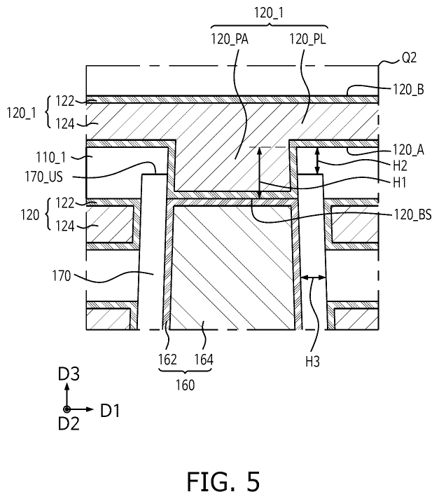

FIG. 1 is a plan view provided to explain a semiconductor memory device according to some example embodiments of the present disclosure. FIG. 2 is a cross-sectional view taken along line A-A of FIG. 1. FIG. 3 is a cross-sectional view taken along line B-B of FIG. 1. FIG. 4 is an enlarged view provided to explain a region Q1 of FIG. 2. FIG. 5 is an enlarged view provided to explain a region Q2 of FIG. 2.

Referring to FIGS. 1 to 5, a semiconductor memory device according to some example embodiments may include a cell structure CELL and a peripheral circuit structure PERI.

The cell structure CELL may include a cell substrate 100, a common source plate 105, a first mold structure MS1, a channel structure CH, a bit line BL, a word line contact 160, a contact spacer 170, a cell wiring structure 180, etc.

The cell substrate 100 may include a cell array region CAR, an extension region EXT, and a through region THR.

A memory cell array including a plurality of memory cells may be formed on the cell array region CAR. The channel structure CH, the first mold structure MS1, the bit line BL, etc. may be disposed on the cell array region CAR. In the present disclosure, the expression “a configuration B is formed (or disposed) on a configuration A” is not limited to the configuration B being formed or disposed in contact with the configuration A. For example, it may also include some example embodiments in which another configuration C is interposed between the configuration B and the configuration A. For example, in the disclosure, the expression that “the configuration B is formed or disposed on configuration A” is not limited to the configuration B being disposed above the configuration A in the drawings. For example, it may also include some example embodiments in which the configuration B is disposed under, or to the right or left side of the configuration A in the drawing.

The extension region EXT may be disposed in a peripheral region of the cell array region CAR. For example, the extension region EXT may surround the cell array region CAR. The word line contact 160, the contact spacer 170, a support structure 150, etc. may be disposed on the extension region EXT.

The through region THR may be disposed outside the extension region EXT. For example, the through region THR may be disposed on one side of the extension region EXT, but some example embodiments are not limited thereto. A source contact 184, an input and output contact, etc. may be disposed in the through region THR.

For example, the cell substrate 100 may include a semiconductor substrate such as a silicon substrate, a germanium substrate, or a silicon-germanium substrate. Alternatively, the cell substrate 100 may include a silicon-on-insulator (SOI) substrate or a germanium-on-insulator (GOI) substrate, etc. In some example embodiments, the cell substrate 100 may include polysilicon (poly Si).

The cell substrate 100 may include a first surface 100_A and a second surface 100_B opposite the first surface 100_A. The first surface 100_A of the cell substrate 100 may be a surface on which the first mold structure MS1 and the channel structure CH are disposed. The first surface 100_A of the cell substrate 100 may be referred to as a front side of the cell substrate 100. The second surface 100_B of the cell substrate 100 may be referred to as a back side of the cell substrate 100.

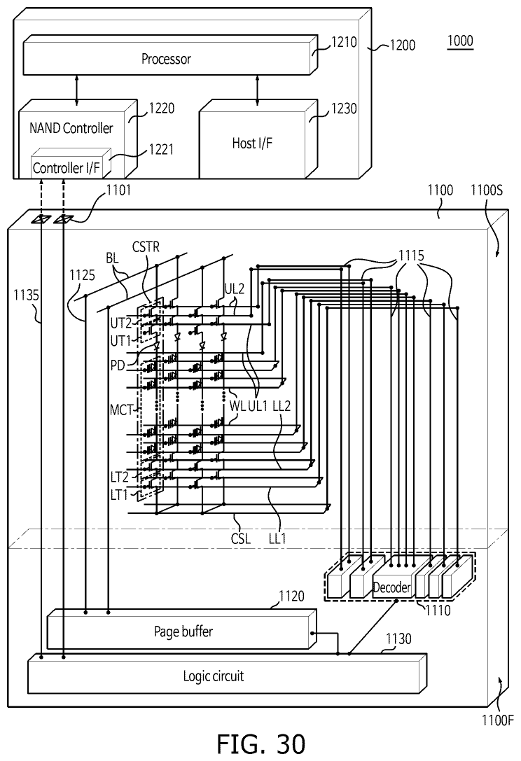

The common source plate 105 may be disposed on the first surface 100_A of the cell substrate 100. The common source plate 105 may be disposed on the cell area CAR, the extension region EXT, and the through region THR. The common source plate 105 may be connected to the channel structure CH. For example, the common source plate 105 may be electrically connected to a semiconductor pattern 142 of the channel structure CH. The common source plate 105 may be connected to the source contact 184 in the through region THR. The common source plate 105 may be provided as a common source line (e.g., a CSL of FIG. 30) of the semiconductor memory device. For example, the common source plate 105 may include polycrystalline silicon or metal doped with impurities, but some example embodiments are not limited thereto.

The first mold structure MS1 may be disposed on the common source plate 105. The first mold structure MS1 may be disposed on the cell array region CAR and the extension region EXT of the cell substrate 100. The first mold structure MS1 may include a plurality of mold insulating layers 110 and a plurality of gate electrodes 120 alternately stacked in a third direction D3. Each of the mold insulating layers 110 and each of the gate electrodes 120 may have a layered structure extending parallel to the first surface 100_A of the cell substrate 100. The gate electrodes 120 may be stacked in order on the common source plate 105 while being spaced apart from each other by the mold insulating layers 110.

In some example embodiments, some of the plurality of gate electrodes 120 may be provided as a ground selection line GSL of a semiconductor memory device. Some other gate electrodes 120 of the plurality of gate electrodes 120 may be provided as a string select line SSL of the semiconductor memory device. For example, a gate electrode 120 adjacent to the common source plate 105, of the plurality of gate electrodes 120, may be provided as the ground selection line GSL. The gate electrode 120 adjacent to the bit line BL, of the plurality of gate electrodes 120, may be provided as the string select line SSL. However, aspects are not limited to the above. The arrangement and number of the ground selection lines GSL and the string select lines SSL may vary.

The mold insulating layer 110 may include an insulating material. For example, the mold insulating layer 110 may include at least one of silicon oxide, silicon nitride, and silicon oxynitride, but some example embodiments are not limited thereto.

The gate electrode 120 may include a conductive material. For example, the gate electrode 120 may include a metal such as tungsten (W), cobalt (Co), nickel (Ni), or a semiconductor material such as silicon, but some example embodiments are not limited thereto.

An interlayer insulating layer 125 may be formed on the first surface 100_A of the cell substrate 100. The interlayer insulating layer 125 may be disposed on the first mold structure MS1 to cover the first mold structure MS1. For example, the interlayer insulating layer 125 may include at least one of silicon oxide, silicon oxynitride, and a low-k material having a dielectric constant lower than that of silicon oxide, but some example embodiments are not limited thereto.

The channel structure CH may be disposed on the cell array region CAR of the cell substrate 100. The channel structure CH may extend in the third direction D3, that is, in a direction perpendicular to the first surface 100_A of the cell substrate 100. The channel structure CH may pass through the first mold structure MS1. For example, the channel structure CH may pass through and intersect each of the plurality of gate electrodes 120. The channel structure CH may have a pillar shape (e.g., a cylindrical shape) extending in the third direction D3. In some example embodiments, the cross section of the channel structure CH may have an inclined side surface such that its width is progressively narrowed toward the cell substrate 100. However, some example embodiments are not limited to the above.

As illustrated in FIG. 4, the channel structure CH may include a filling insulating layer 140, the semiconductor pattern 142, and an information storage layer 144.

The semiconductor pattern 142 may extend in the third direction D3 and pass through the mold structure MS. Although the illustrated semiconductor pattern 142 has a cup shape, some example embodiments are not limited thereto. The semiconductor pattern 142 may have various shapes such as a cylindrical shape, a rectangular cylindrical shape, a filled filler shape, etc. For example, the semiconductor pattern 142 may include a semiconductor material such as a single crystal silicon, a polycrystalline silicon, an organic semiconductor material, a carbon nanostructure, etc., although some example embodiments are not limited thereto.

The information storage layer 144 may be interposed between the semiconductor pattern 142 and each of the gate electrodes 120. For example, the information storage layer 144 may extend along an outer surface of the semiconductor pattern 142. For example, the information storage layer 144 may include at least one of silicon oxide, silicon nitride, silicon oxynitride, and a high-k material having a higher dielectric constant than silicon oxide. For example, the high-k material may include at least one of aluminum oxide, hafnium oxide, lanthanum oxide, tantalum oxide, titanium oxide, lanthanum hafnium oxide, lanthanum aluminum oxide, dysprosium scandium oxide, and a combination thereof.

In some example embodiments, the channel structures CH may be disposed in a zigzag form. For example, as illustrated in FIG. 1, the channel structures CH may be disposed to cross each other in first and second directions D1 and D2. The channel structures CH disposed in the zigzag form may further improve the degree of integration of the semiconductor memory device. In some example embodiments, the channel structures CH may be disposed in a honeycomb form.

In some example embodiments, the information storage layer 144 may include multiple layers. The information storage layer 144 may include a tunnel insulating layer 144_1, a charge storage layer 144_2, and a blocking insulating layer 144_3, which may be stacked in order on the outer surface of the semiconductor pattern 142.

For example, the tunnel insulating layer 144_1 may include silicon oxide or a high-k material (e.g., aluminum oxide (Al₂O₃), hafnium oxide (HfO₂)) having a higher dielectric constant than the silicon oxide. For example, the charge storage layer 144_2 may include the silicon nitride. For example, the blocking insulating layer 144_3 may include the silicon oxide or a high-k material (e.g., aluminum oxide (Al₂O₃), hafnium oxide (HfO₂)) having a higher dielectric constant than the silicon oxide.

In some example embodiments, the channel structure CH may further include the filling insulating layer 140. The filling insulating layer 140 may be formed to fill the inside of the cup-shaped semiconductor pattern 142. For example, the filling insulating layer 140 may include an insulating material, for example, silicon oxide, but some example embodiments are not limited thereto.

In some example embodiments, a channel pad 132 may be disposed on the channel structure CH. The channel pad 132 may be formed to be connected to the semiconductor pattern 142. For example, the channel pad 132 may be provided in the interlayer insulating layer 125 to be connected to one end of the semiconductor pattern 142. For example, the channel pad 132 may include polysilicon doped with impurities, but some example embodiments are not limited thereto.

The first mold structure MS1 may be divided by the word line cutting regions WCF to form a memory cell block (e.g., BLK of FIG. 1). For example, the word line cutting region WCF may include at least one of insulating material, silicon oxide, silicon nitride, and silicon oxynitride, but some example embodiments are not limited thereto.

The bit lines BL may be formed on the first mold structure MS1. The bit lines BL may intersect the word line cutting regions WCF. For example, each of the bit lines BL may extend in the second direction D2. The bit lines BL may be disposed along the first direction D1 while being spaced apart from each other.

The bit lines BL may be connected to the channel structures CH disposed along the second direction D2. A bit line contact 136 may be formed in the interlayer insulating layer 125. The bit line BL may be electrically connected to the channel structure CH through the bit line contact 136 and the channel pad 132.

The word line contact 160 may be disposed on the extension region EXT of the cell substrate 100. The word line contact 160 may extend in the third direction D3 and may be connected to the gate electrode 120. For example, the word line contact 160 may pass through a portion of the first mold structure MS1 to be connected to the corresponding gate electrode 120.

The contact spacer 170 may be disposed on a side surface of the word line contact 160. The contact spacer 170 may extend in the third direction D3 along the side surface of the word line contact 160. The contact spacer 170 may surround the word line contact 160. The contact spacer 170 may include an insulating material. For example, the contact spacer 170 may include a silicon oxide-based insulating material.

Hereinafter, shapes of the gate electrode 120, the word line contact 160, and the contact spacer 170 will be described in detail with reference to FIG. 5.

The plurality of gate electrodes 120 may include a first gate electrode 120_1. The first gate electrode 120_1 may refer to the gate electrode 120 electrically connected to the word line contact 160.

The first gate electrode 120_1 may include a plate part 120_PL and a pad part 120_PA.

The plate part 120_PL may extend in the first direction D1. The plate part 120_PL may include a first surface 120_A and a second surface 120_B opposite the first surface 120_A. The second surface 120_B of the plate part 120_PL may be a surface opposite the first surface 100_A of the cell substrate 100. A first mold insulating layer 110_1 may be disposed on the first surface 120_A of the plate part 120_PL.

The pad part 120_PA may protrude from the first surface 120_A of the plate part 120_PL toward the word line contact 160. At least a portion of the pad part 120_PA may be disposed in the first mold insulating layer 110_1. For example, at least a portion of the pad part 120_PA may overlap the first mold insulating layer 110_1 in the first direction D1.

A lower portion of the pad part 120_PA may be disposed in the contact spacer 170. That is, the lower portion of the pad part 120_PA may be inserted into the contact spacer 170. The lower portion of the pad part 120_PA may be a portion of the pad part 120_PA adjacent to the word line contact 160, and the upper portion of the pad part 120_PA may be a portion of the pad part 120_PA adjacent to the plate part 120_PL.

The pad part 120_PA may be in contact with the word line contact 160. One surface 120_BS of the pad part 120_PA may be in contact with an upper surface of the word line contact 160. That is, the one surface 120_BS of the pad part 120_PA may be a boundary surface between the word line contact 160 and the first gate electrode 120_1. The one surface 120_BS of the pad part 120_PA may be disposed in the contact spacer 170. The one surface 120_BS of the pad part 120_PA may be referred to as a lower surface of the pad part 120_PA.

In the present disclosure, the terms “upper”, “lower”, “upper surface”, and “lower surface” are used for convenience of description, but some example embodiments are not limited thereto. The terms “upper”, “lower”, “upper surface”, and “lower surface” may be described based on the illustrations in the drawings, and the terms referring to the vertical relationship may change upon vertical rotation of the drawing.

In some example embodiments, a distance H2 from the first surface 120_A of the plate part 120_PL to an end portion 170_US of the contact spacer 170 may be different from a distance H1 from the first surface 120_A of the plate part 120_PL to the one surface 120_BS of the pad part 120_PA. For example, the distance H2 from the first surface 120_A of the plate part 120_PL to the end portion 170_US of the contact spacer 170 may be less than the distance H1 from the first surface 120_A of the plate part 120_PL to the one surface 120_BS of the pad part 120_PA. The distance H1 from the first surface 120_A of the plate part 120_PL to the one surface 120_BS of the pad part 120_PA may be a thickness in the third direction D3 of the pad part 120_PA. The end portion 170_US of the contact spacer 170 may be referred to as an upper surface of the contact spacer 170.

An uppermost end of the contact spacer 170 may be disposed in the first mold insulating layer 110_1. The end portion 170_US of the contact spacer 170 may be disposed in the first mold insulating layer 110_1. The end portion 170_US of the contact spacer 170 may be spaced apart from the first gate electrode 120_1 in the third direction D3. An inner wall of the contact spacer 170 may be in contact with the word line contact 160 and the pad part 120_PA.

A thickness H3 of the contact spacer 170 in the first direction D1 may be less than the thickness H1 of the pad part 120_PA in the third direction D3. The contact spacer 170 may have a constant thickness. For example, the thickness H3 of the contact spacer 170 may be constant in the first direction D1. For example, the contact spacer 170 may have a same constant thickness H3 at positions of the contact spacer 170 along the third direction D3. However, some example embodiments are not limited to the above.

The word line contact 160 and the contact spacer 170 may pass through a portion of the first mold structure MS1. For example, the word line contact 160 and the contact spacer 170 may pass through one or more gate electrodes 120 disposed on one side (e.g., on a lower portion) of the first gate electrode 120_1. The word line contact 160 and the contact spacer 170 may pass through one or more mold insulating layers 110 disposed on one side (e.g., on a lower portion) of the first mold insulating layer 110_1. For example, the word line contact 160 and the contact spacer 170 may pass through the plurality of gate electrodes 120 disposed between the first gate electrode 120_1 and the bit line BL and through the plurality of mold insulating layers 110 disposed between the first mold insulating layer 110_1 and the bit line BL.

In some example embodiments, the gate electrode 120 may include an electrode barrier layer 122 and an electrode filling layer 124. For example, the first gate electrode 120_1 may include the electrode barrier layer 122 and the electrode filling layer 124. The electrode barrier layer 122 may be disposed along an outer surface of the first gate electrode 120_1. For example, the electrode barrier layer 122 may be disposed on the word line contact 160 and the mold insulating layer 110 which are in contact with the first gate electrode 120_1. The electrode filling layer 124 may fill an inner space of the electrode barrier layer 122.

In some example embodiments, the word line contact 160 may include a contact barrier layer 162 and a contact filling layer 164. The contact barrier layer 162 may be disposed along an outer surface of the word line contact 160. For example, the contact barrier layer 162 may be disposed on the contact spacer 170 and the pad part 120_PA which are in contact with the word line contact 160. The contact filling layer 164 may fill an inner space of the contact barrier layer 162.

In some example embodiments, the electrode barrier layer 122 and the contact barrier layer 162 may be in contact with each other. A surface on which the electrode barrier layer 122 and the contact barrier layer 162 contact each other may be the one surface 120_BS of the pad part 120_PA.

Each of the electrode barrier layer 122 and the contact barrier layer 162 may include at least one of tantalum (Ta), tantalum nitride (TaN), titanium (Ti), titanium nitride (TiN), titanium silicon nitride (TiSiN), ruthenium (Ru), cobalt (Co), nickel (Ni), nickel boron (NiB), tungsten (W), tungsten nitride (WN), tungsten carbon nitride (WCN), zirconium (Zr), zirconium nitride (ZrN), vanadium (V), vanadium nitride (VN), niobium (Nb), niobium nitride (Nb), platinum (Pt), iridium (Ir), rhodium (Rh), and a two-dimensional (2D) material.

Each of the electrode filling layer 124 and the contact filling layer 164 may include at least one of aluminum (Al), tungsten (W), cobalt (Co), ruthenium (Ru), silver (Ag), gold (Au), manganese (Mn), and molybdenum (Mo).

Unlike the illustration, the first gate electrode 120_1 may not include the electrode barrier layer 122, and the word line contact 160 may not include the contact barrier layer 162. In this some example embodiments, the electrode filling layer 124 and the contact filling layer 164 may be in contact with each other.

A word line via 166 may be disposed on the word line contact 160. The word line via 166 may be disposed in the interlayer insulating layer 125. The word line contact 160 may be electrically connected to the cell wiring structure 180 through the word line via 166.

The support structure 150 may be disposed on the extension region EXT of the cell substrate 100. The support structure 150 may be disposed around the word line contact 160. For example, four support structures 150 may be disposed around one word line contact 160. However, some example embodiments are not limited to the above. For example, three support structures 150 may be disposed around one word line contact 160. The support structure 150 may support the first mold structure MS1 or the word line contact 160 to limit and/or prevent the first mold structure MS1 or the word line contact 160 from collapsing or falling.

The support structure 150 may include a vertical part 150_V extending in the third direction D3 and a horizontal part 150_H extending in a fourth direction D4. The fourth direction D4 may be a direction parallel to the first surface 100_A of the cell substrate 100. The vertical part 150_V of the support structure 150 may be formed in a shape similar to that of the channel structure CH. The horizontal part 150_H of the support structure 150 may extend in the first and second directions D1 and D2. The horizontal part 150_H of the support structure 150 may be disposed at the same level as the gate electrode 120. In the present disclosure, by the “same level”, it may mean that the horizontal part 150_H is disposed at the same height in the third direction D3 with respect to the first surface 100_A of the cell substrate 100. The expression “same” as used herein may mean the substantial sameness that includes manufacturing tolerances.

The support structure 150 may include an insulating material. For example, the support structure 150 may include a silicon oxide-based insulating material. However, some example embodiments are not limited to the above.

The cell wiring structure 180 may be formed on the first mold structure MS1. For example, a first wiring insulating layer 182 may be formed on the interlayer insulating layer 125, and the cell wiring structure 180 may be formed in the first wiring insulating layer 182. The cell wiring structure 180 may be electrically connected to the bit line BL and the word line contact 160. Accordingly, the cell wiring structure 180 may be electrically connected to the channel structure CH and the gate electrode 120. The number, arrangement, etc. of the layers of the illustrated cell wiring structure 180 are merely illustrative, and some example embodiments are not limited thereto.

The peripheral circuit structure PERI may include a peripheral circuit substrate 300, a peripheral circuit element 360, and a peripheral circuit wiring structure 380.

For example, the peripheral circuit substrate 300 may include a semiconductor substrate such as a silicon substrate, a germanium substrate, or a silicon-germanium substrate. Alternatively, the peripheral circuit substrate 300 may also include a silicon-on-insulator (SOI) substrate or a germanium-on-insulator (GOI) substrate, etc.

The peripheral circuit element 360 may be formed on the peripheral circuit substrate 300. The peripheral circuit element 360 may form a peripheral circuit that controls an operation of the semiconductor memory device. For example, the peripheral circuit element 360 may include a logic circuit 1130, a page buffer 1120, a decoder 1110, etc. of FIG. 30. In the following description, the surface of the peripheral circuit substrate 300 on which the peripheral circuit element 360 is disposed may be referred to as a front side of the peripheral circuit substrate 300. Conversely, the surface of the peripheral circuit substrate 300 opposite the front side of the peripheral circuit substrate 300 may be referred to as a back side of the peripheral circuit substrate 300.

For example, the peripheral circuit element 360 may include a transistor, but some example embodiments are not limited thereto. For example, the peripheral circuit element 360 may include not only various active elements such as transistors, but also various passive elements such as capacitors, registers, and inductors.

The peripheral circuit wiring structure 380 may be formed on the peripheral circuit element 360. For example, a second wiring insulating layer 340 may be formed on the front side of the peripheral circuit substrate 300, and the peripheral circuit wiring structure 380 may be formed in the second wiring insulating layer 340. The peripheral circuit wiring structure 380 may be electrically connected to the peripheral circuit element 360. The number, arrangement, etc. of the layers of the peripheral circuit wiring structure 380 illustrated are merely examples, and aspects are not limited thereto.

In some example embodiments, the cell structure CELL may be stacked on the peripheral circuit structure PERI. For example, the cell structure CELL may be stacked on the second wiring insulating layer 340.

In some example embodiments, the first surface 100_A of the cell substrate 100 may be opposite the peripheral circuit structure PERI. For example, the front side (e.g., the first surface 100_A) of the cell substrate 100 may be opposite the front side of the peripheral circuit substrate 300.

The semiconductor memory device according to some example embodiments may have a chip-to-chip (C2C) structure. The C2C structure refers to manufacturing an upper chip including the cell structure (CELL) on a first wafer (e.g., the cell substrate 100), manufacturing a lower chip including the peripheral circuit structure (PERI) on the second wafer (e.g., the peripheral circuit substrate 300) that is different from the first wafer, and connecting the upper and lower chips to each other by a bonding method.

In some example embodiments, by the bonding method, it may mean a method of electrically connecting a first bonding metal 185 formed on the lowermost metal layer of the upper chip and a second bonding metal 385 formed on the uppermost metal layer of the lower chip to each other. For example, if the first bonding metal 185 and the second bonding metal 385 are formed of copper (Cu), the bonding method may be a Cu—Cu bonding method. However, this is only an example, and in some example embodiments the first bonding metal 185 and the second bonding metal 385 may be formed of various other metals such as aluminum (Al) or tungsten (W).

As the first bonding metal 185 and the second bonding metal 385 are bonded to each other, the cell wiring structure 180 may be connected to the peripheral circuit wiring structure 380. Accordingly, the bit line BL and/or each of the gate electrodes 120 may be electrically connected to the peripheral circuit element 360.

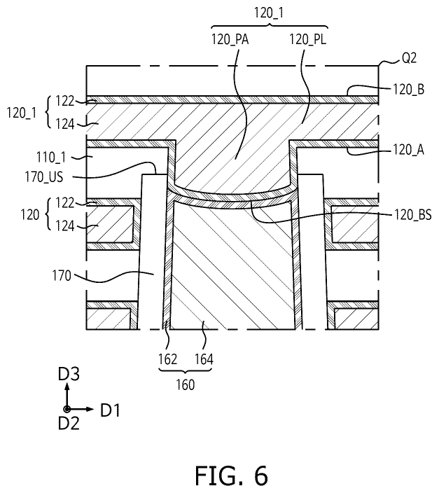

FIGS. 6 to 9 are diagrams provided to explain a semiconductor memory device according to some example embodiments of the present disclosure. For reference, FIGS. 6 to 9 may correspond to an enlarged view of the Q2 region of FIG. 2. For convenience of description, different configurations from those described in FIGS. 1 to 5 will be mainly described.

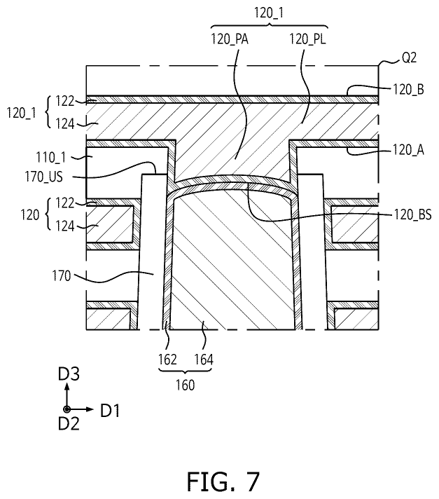

Referring to FIGS. 6 and 7, in the semiconductor memory device according to some example embodiments, the pad part 120_PA of the first gate electrode 120_1 may be in contact with the word line contact 160. For example, the one surface 120_BS of the pad part 120_PA may be in contact with the upper surface of the word line contact 160.

As illustrated in FIG. 6, the one surface 120_BS of the pad part 120_PA may have a convex shape curved outward toward the word line contact 160. That is, a central portion of the one surface 120_BS of the pad part 120_PA may be disposed lower along the third direction D3 than edge portions of the one surface 120_BS. The upper surface of the word line contact 160 may have a concave shape corresponding to the shape of the pad part 120_PA.

As illustrated in FIG. 7, the one surface 120_BS of the pad part 120_PA may have a concave shape curved inward from the word line contact 160. That is, a central portion of the one surface 120_BS of the pad part 120_PA may be disposed higher along the third direction D3 than edge portions of the one surface 120_BS. The upper surface of the word line contact 160 may have a convex shape corresponding to the shape of the pad part 120_PA.

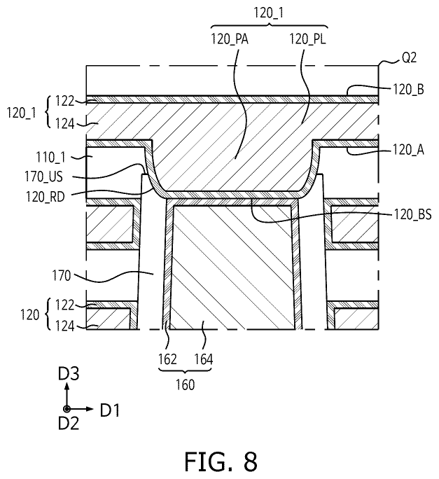

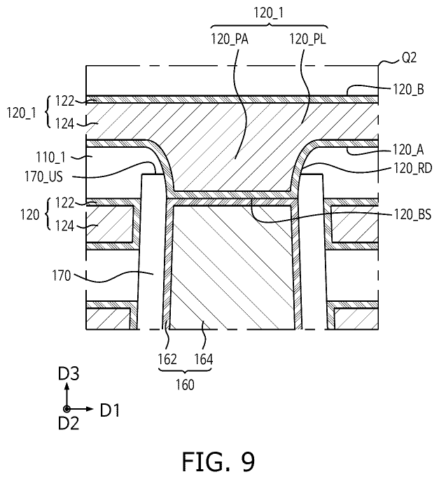

Referring to FIGS. 8 and 9, in the semiconductor memory device according to some example embodiments, the diameter of the pad part 120_PA in the first direction D1 may not be constant. For example, the diameter of the pad part 120_PA in the first direction D1 may decrease from the plate part 120_PL to (e.g., toward) the word line contact 160.

The side surface of the pad part 120_PA may include a rounding part 120_RD. The rounding portion 120_RD may be in contact with the contact spacer 170. For example, the inner wall of the upper portion of the contact spacer 170 may be in contact with the rounding portion 120_RD. The rounding part 120_RD may have a convex shape as illustrated in FIG. 8, and a concave shape as illustrated in FIG. 9.

In some example embodiments, the thickness of the contact spacer 170 may not be constant in the first direction D1. For example, the thickness in the first direction D1 of a portion of the contact spacer 170 that is in contact with the pad part 120_PA may be less than the thickness in the first direction D1 of a portion of the contact spacer 170 that is in contact with the word line contact 160. The thickness of the portion of the contact spacer 170 in contact with the pad part 120_PA in the first direction D1 may progressively decrease toward the one surface 120_BS of the pad part 120_PA.

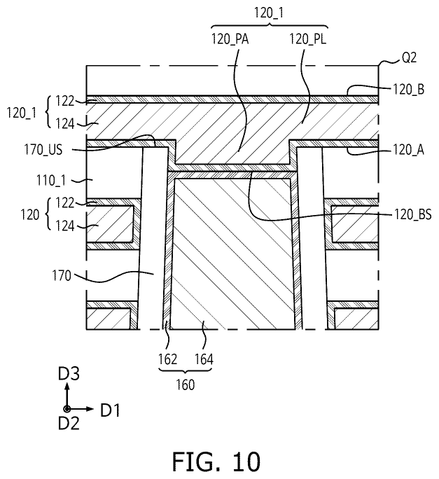

FIGS. 10 to 12 are diagrams provided to explain a semiconductor memory device according to some example embodiments of the present disclosure. For reference, FIGS. 10 to 12 may correspond to an enlarged view of the Q2 region of FIG. 2. For convenience of description, different configurations from those described in FIGS. 1 to 5 will be mainly described.

Referring to FIG. 10, in the semiconductor memory device according to some example embodiments, the contact spacer 170 may pass through the first mold insulating layer 110_1. The end portion 170_US of the contact spacer 170 may be disposed on the first surface 120_A of the plate part 120_PL. The end portion 170_US of the contact spacer 170 may be disposed in the same plane as the first surface 120_A of the plate part 120_PL.

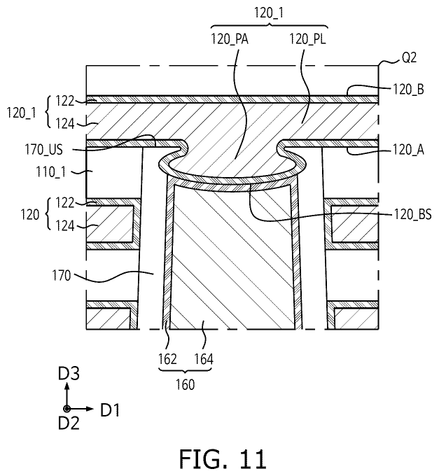

Referring to FIG. 11, in the semiconductor memory device according to some example embodiments, the pad part 120_PA may protrude from the first surface 120_A of the plate part 120_PL. The pad part 120_PA may have an elliptical shape. In the first direction D1, a width of the pad part 120_PA may be greater than a width of an upper portion of the word line contact 160. By the “width of the pad part 120_PA”, it may mean a major axis of an ellipse.

A portion of the contact spacer 170 may be disposed between the pad part 120_PA and the plate part 120_PL. The inner wall of the contact spacer 170 in contact with the pad part 120_PA may have a recessed shape corresponding to the shape of the pad part 120_PA.

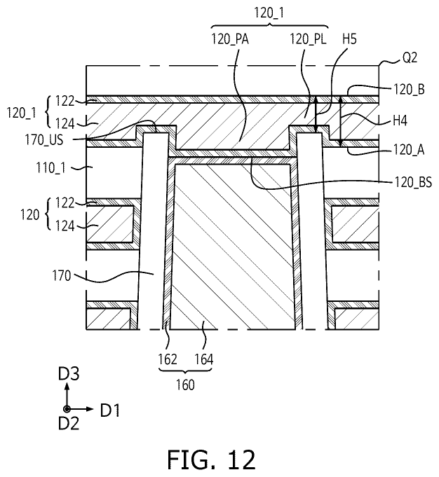

Referring to FIG. 12, in the semiconductor memory device according to some example embodiments, the upper portion of the contact spacer 170 may pass through the first surface 120_A of the plate part 120_PL. The end portion 170_US of the contact spacer 170 may be disposed in the first gate electrode 120_1. For example, a distance H4 from the second surface 120_B of the plate part 120_PL to the first surface 120_A of the plate part 120_PL may be greater than a distance H5 from the second surface 120_B of the plate part 120_PL to the end portion 170_US of the contact spacer 170.

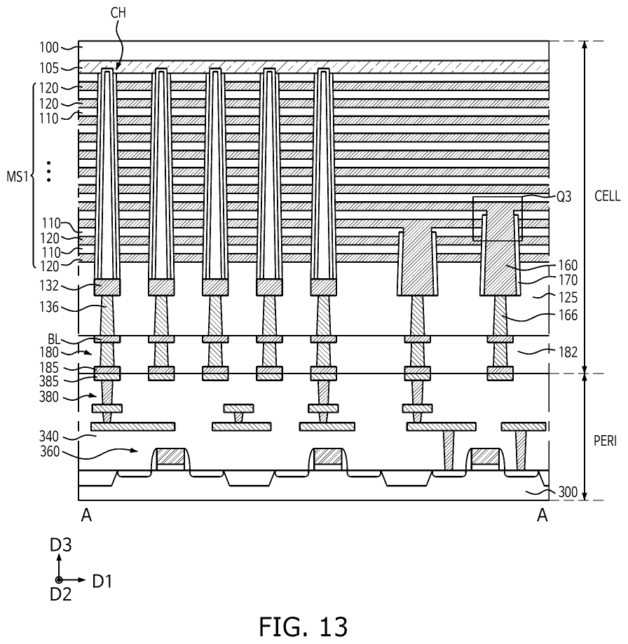

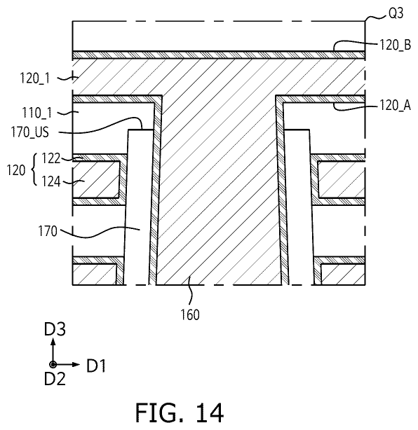

FIGS. 13 and 14 are diagrams provided to explain a semiconductor memory device according to some example embodiments of the present disclosure. For reference, FIG. 13 may correspond to a cross-sectional view taken along line A-A of FIG. 1. FIG. 14 is an enlarged view provided to explain a region Q3 of FIG. 13. For convenience of description, different configurations from those described in FIGS. 1 to 5 will be mainly described.

Referring to FIGS. 13 and 14, in the semiconductor memory device according to some example embodiments, the word line contact 160 and the first gate electrode 120_1 may be unitary formed. For example, the word line contact 160 and the gate electrode 120_1 may be formed in the same process. A boundary surface between the word line contact 160 and the first gate electrode 120_1 may not be distinguished. For example, in some example embodiments a boundary surface does not exist between the word line contact 160 and the first gate electrode 120_1.

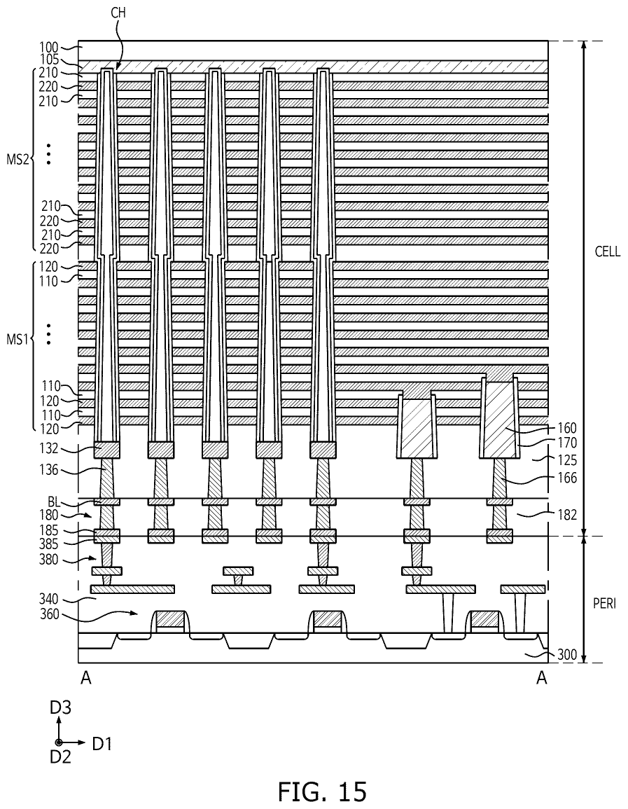

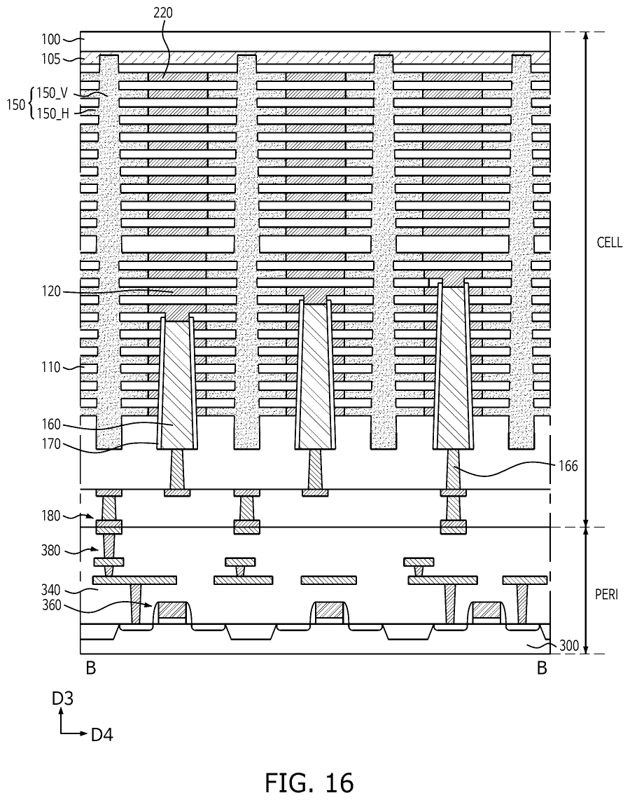

FIGS. 15 and 16 are diagrams provided to explain a semiconductor memory device according to some example embodiments of the present disclosure. For reference, FIG. 15 may correspond to a cross-sectional view taken along line A-A of FIG. 1, and FIG. 16 may correspond to a cross-sectional view taken along line B-B of FIG. 1. For convenience of description, different configurations from those described in FIGS. 1 to 5 will be mainly described.

Referring to FIGS. 15 and 16, in the semiconductor memory device according to some aspects, a second mold structure MS2 and the first mold structure MS1 may be stacked in order on the cell substrate 100.

The second mold structure MS2 may be disposed on the cell array region CAR and the extension region EXT of the cell substrate 100. The second mold structure MS2 may include a plurality of mold insulating layers 210 and a plurality of gate electrodes 220 alternately stacked in the third direction D3. Each of the mold insulating layers 210 and each of the gate electrodes 220 may have a layered structure extending parallel to the first surface 100_A of the cell substrate 100. The gate electrodes 220 may be sequentially stacked on the common source plate 105 while being spaced apart from each other by the mold insulating layers 210.

The first mold structure MS1 may be disposed on the second mold structure MS2. The first mold structure MS1 may include a plurality of mold insulating layers 110 and a plurality of gate electrodes 120 alternately stacked in a third direction D3. A cell insulating layer may be disposed between the first mold structure MS1 and the second mold structure MS2. The cell insulating layer may cover a lower surface of the second mold structure MS2. The first mold structure MS1 may be formed on the cell insulating layer.

The channel structure CH may extend in the third direction D3 and may pass through the first mold structure MS1 and the second mold structure MS2. The channel structure CH may have a bent portion between the first mold structure MS1 and the second mold structure MS2.

The word line contact 160 may extend in the third direction and pass through the first mold structure MS1 and the second mold structure MS2. A plurality of word line contacts 160 may be electrically connected to the gate electrode 120 of the first mold structure MS1 and the gate electrode of the second mold structure MS2. For example, the word line contact 160 connected to the gate electrode 120 of the first mold structure MS1 may pass through a portion of the first mold structure MS1. The word line contact 160 connected to the gate electrode 120 of the second mold structure MS2 may pass through the first mold structure MS1 and then a portion of the second mold structure MS2.

Although FIG. 15 and FIG. 16 illustrate that the number of mold structures MS1 and MS2 is two, some example embodiments are not limited thereto. For example, the number of the mold structures MS1 and MS2 may be three or four or more.

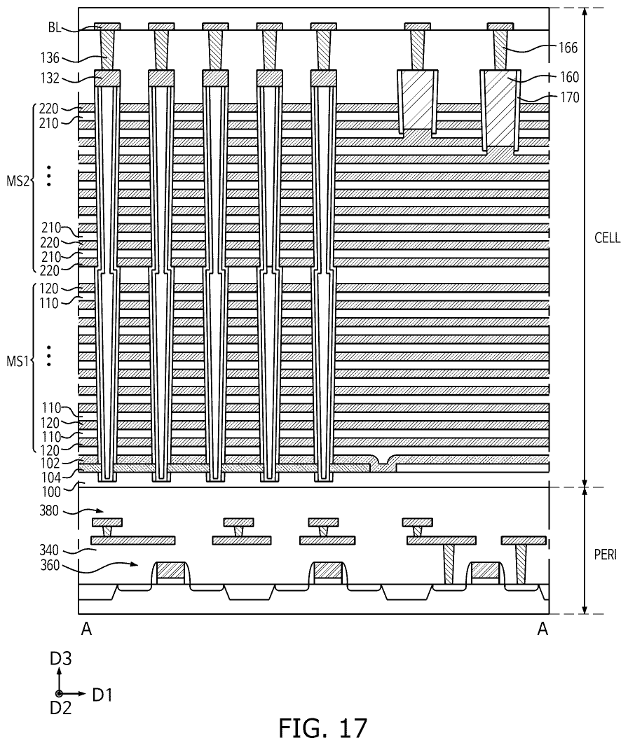

FIG. 17 is a diagram illustrating a semiconductor memory device according to some example embodiments of the present disclosure. For reference, FIG. 17 may be a view corresponding to a cross-sectional view taken along line A-A of FIG. 1. For convenience of description, different configurations from those described in FIGS. 1 to 5 will be mainly described.

Referring to FIG. 17, the semiconductor memory device according to some example embodiments may include a cell structure CELL and a peripheral structure PERI.

The cell structure CELL may be disposed on an upper portion of the peripheral structure PERI. The description of the peripheral structure PERI may be the same as that described in FIGS. 1 to 5.

The cell structure CELL may include the cell substrate 100, the mold structures MS1 and MS2, the channel structure CH, the bit line BL, the word line contact 160, the contact spacer 170, etc.

The cell substrate 100 may be disposed on the peripheral structure PERI. For example, the cell substrate 100 may include a semiconductor substrate such as a silicon substrate, a germanium substrate, or a silicon-germanium substrate. Alternatively, the cell substrate 100 may include a silicon-on-insulator (SOI) substrate or a germanium-on-insulator (GOI) substrate, etc. In some example embodiments, the cell substrate 100 may include impurities. For example, the cell substrate 100 may include n-type impurities (e.g., phosphorus (P), arsenic (As), etc.).

Source structures 102 and 104 may be formed on the cell substrate 100. The source structures 102 and 104 may be disposed between the cell substrate 100 and the mold structures MS1 and MS2. For example, the source structures 102 and 104 may extend along the upper surface of the cell substrate 100. The source structures 102 and 104 may be formed to be connected to a semiconductor pattern of the channel structure CH. For example, the second source layer 104 of the source structures 102 and 104 may pass through the information storage layer 144 and contact the semiconductor pattern 142 of the channel structure CH (e.g., see FIG. 4). The source structures 102 and 104 may be provided as a common source line (e.g., the CSL of FIG. 30) of the semiconductor memory device. For example, the source structures 102 and 104 may include a polysilicon or metal doped with impurities, but are not limited thereto.

In some example embodiments, the channel structure CH may pass through the source structures 102 and 104. For example, a lower portion of the channel structure CH may pass through the source structures 102 and 104 and may be disposed in the cell substrate 100.

In some example embodiments, the source structures 102 and 104 may include multiple layers. For example, the source structures 102 and 104 may include the first source layer 102 and the second source layer 104 which are stacked in order on the cell substrate 100. Each of the first source layer 102 and the second source layer 104 may include polysilicon doped with impurities or polysilicon undoped with impurities, but some example embodiments are not limited thereto. The second source layer 104 may be provided as a common source line (e.g., CSL of FIG. 30) of the semiconductor memory device which is in contact with the semiconductor pattern (e.g., 142 in FIG. 4). The first source layer 102 may be used as a support layer for limiting and/or preventing the mold stack (e.g., the mold structures MS1 and MS2) from collapsing or falling in a replacement process for forming the second source layer 104.

Although not illustrated, a base insulating layer may be interposed between the cell substrate 100 and the first source structures 102 and 104. For example, the base insulating layer may include at least one of silicon oxide, silicon nitride, and silicon oxynitride, but is not limited thereto.

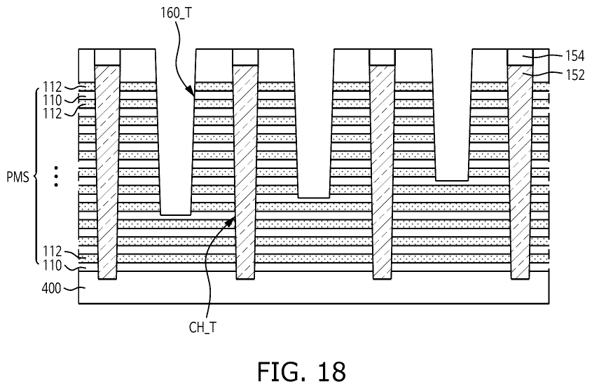

FIGS. 18 to 24 are diagrams showing intermediate stages, provided to explain a method for manufacturing a semiconductor memory device according to some example embodiments of the present disclosure.

Referring to FIG. 18, a pre-stack structure PMS may be formed on a pre-substrate 400. The pre-stack structure PMS may include the plurality of mold insulating layers 110 and mold sacrificial layers 112 that are alternately stacked on each other.

A dummy channel trench CH_T may be formed in the pre-stack structure PMS. A first sacrificial layer 152 may be filled in the dummy channel trench CH_T. A first capping layer 154 may be formed on the first sacrificial layer 152.

A word line contact trench 160_T may be formed in the pre-stack structure PMS. The word line contact trench 160_T may pass through a portion of the pre-stack structure PMS. In some example embodiments, a bottom surface of the word line contact trench 160_T may expose the mold insulating layer 110. However, some example embodiments are not limited to the above. For example, the bottom surface of the word line contact trench 160_T may expose the mold sacrificial layer 112.

The word line contact trench 160_T may have a tapered shape that is progressively narrowed in width toward the pre-substrate 400. However, some example embodiments are not limited to the above. For example, the width of the word line contact trench 160_T may be constant.

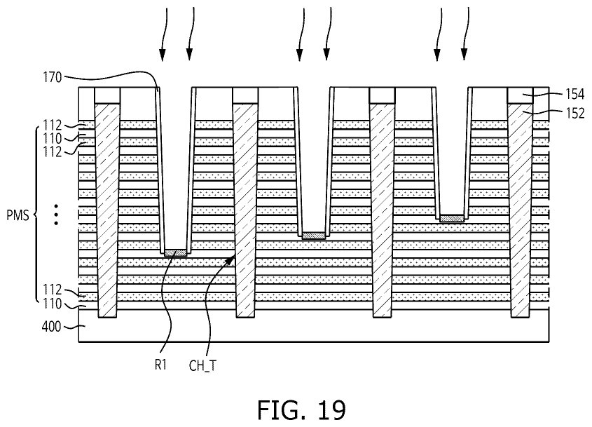

Referring to FIGS. 18 and 19, the contact spacer 170 may be formed on the sidewall and the bottom surface of the word line contact trench 160_T, and an ion implantation process may be performed on the bottom surface of the contact spacer 170.

For example, the contact spacer 170 may be formed along the sidewall and the bottom surface of the word line contact trench 160_T. For example, the contact spacer 170 may be formed using any one of chemical vapor deposition (CVD), low pressure image vapor deposition (LP-CVD), plasma enhanced CVD (PE-CVD), and atomic layer deposition (ALD).

In some example embodiments, the contact spacer 170 may be conformally formed on the word line contact trench 160_T.

The ion implantation process may be performed on the contact spacer 170 to form an ion implantation region R1. For example, the ion implantation process may be performed using an element such as phosphorus, arsenic, etc. The ion implantation process may include a single ion implantation process or a multi ion implantation process. The ion implantation region R1 may be formed in the bottom portion of the contact spacer 170 by the ion implantation process.

Although it is illustrated that the ion implantation region R1 is formed only at the bottom of the contact spacer 170, some example embodiments are not limited thereto. The ion implantation region R1 may also be formed in the mold insulating layer 110 disposed on the lower portion of the bottom surface of the contact spacer 170. For example, the ion implantation region R1 may be in contact with the mold sacrificial layer 112 disposed on the lower portion of the contact spacer 170.

Although it is illustrated that the ion implantation region R1 has a rectangular shape, some example embodiments are not limited thereto. For example, the ion implantation region R1 may have various shapes such as ellipse, trapezoid, etc.

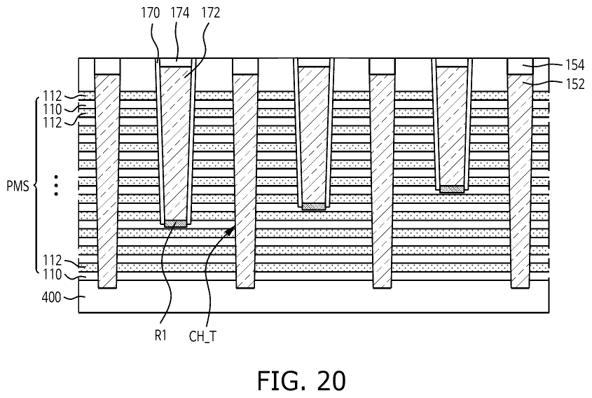

Referring to FIG. 20, a second sacrificial layer 172 and a second capping layer 174 may be formed on the contact spacer 170. For example, the second sacrificial layer 172 may be formed in a space in the contact spacer 170. The second capping layer 174 may be formed on the second sacrificial layer 172.

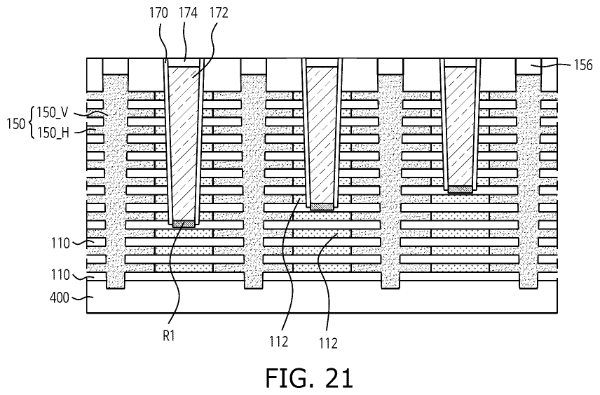

Referring to FIGS. 20 and 21, a portion of the first sacrificial layer 152 and the mold sacrificial layer 112 may be removed, and the support structure 150 may be formed.

For example, the first capping layer 154 and the first sacrificial layer 152 may be removed. The first sacrificial layer 152 may be removed, and a portion of the mold sacrificial layer 112 may be removed. For example, a portion of the mold sacrificial layer 112 adjacent to the first sacrificial layer 152 may be removed.

The support structure 150 may be formed in a portion from which the first sacrificial layer 152 and the mold sacrificial layer 112 were removed. The support structure 150 may include the vertical part 150_V that extends vertically, and the horizontal part 150_H that extends horizontally. The vertical part 150_V may be formed in a portion from which the first sacrificial layer 152 was removed, and the horizontal part 150_H may be formed in a portion from which the mold sacrificial layer 112 was removed. A third capping layer 156 may be formed on the support structure 150.

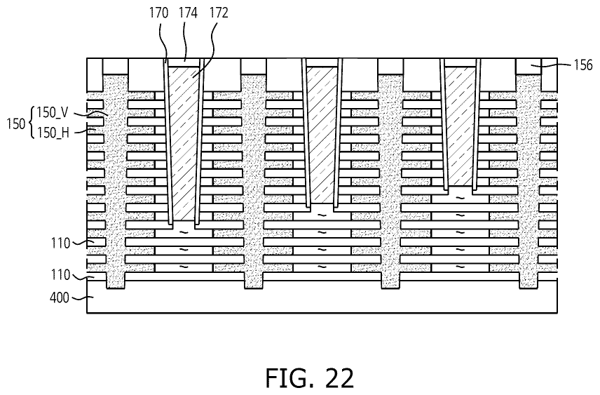

Referring to FIGS. 21 and 22, the mold sacrificial layer 112 and the ion implantation region R1 may be removed.

For example, the mold sacrificial layer 112 may be removed by an etching solution. When the mold sacrificial layer 112 is removed, the ion implantation region R1 may also be removed. Since the ion implantation region R1 has a higher etch rate than the contact spacer 170, the contact spacer 170 may not be removed when the ion implantation region R1 is removed.

In some example embodiments, a portion of the contact spacer 170 adjacent to the ion implantation region R1 may be removed when the ion implantation region R1 is removed. The shape of the contact spacer 170 after the removal of the portion mentioned above may be similar to those shown in FIGS. 8 and 9.

The ion implantation region R1 may be removed, and a lower portion of the second sacrificial layer 172 may be exposed.

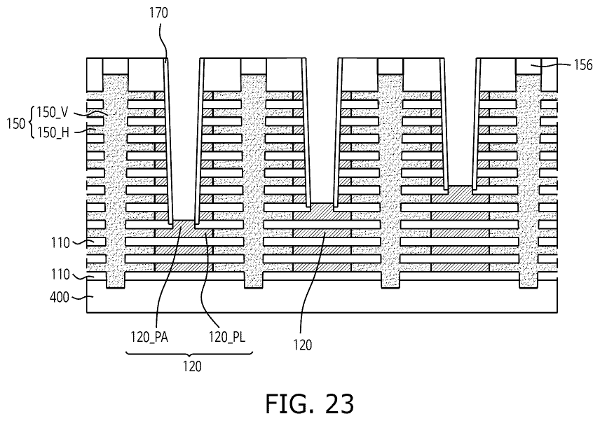

Referring to FIGS. 22 and 23, the gate electrode 120 may be formed, and the second sacrificial layer 172 and the second capping layer 174 may be removed.

For example, the gate electrode 120 may be formed on a portion from which the mold sacrificial layer 112 and the ion implantation region R1 were removed. The gate electrode 120 may be disposed between the mold insulating layers 110. The gate electrode 120 may include the plate part 120_PL and the pad part 120_PA. The pad part 120_PA may be formed in a portion from which the ion implantation region R1 was removed. The pad part 120_PA may be disposed higher than an end portion of the contact spacer 170.

Although not illustrated, the gate electrode 120 may include an electrode barrier layer and an electrode filling layer. The description of the electrode barrier layer and the electrode filling layer may be the same as that described in FIG. 5.

As the semiconductor memory device is integrated, a contact failure may occur between the gate electrode 120 and the word line contact 160. For example, it may be difficult to etch the bottom surface of the contact spacer 170 formed on the word line contact trench 160_T with a high aspect ratio. If the bottom surface of the contact spacer 170 is not etched, a defect may occur, in which the gate electrode 120 and the word line contact 160 are not in contact.

In the semiconductor memory device according to some example embodiments of the present disclosure, the ion implantation region R1 of the contact spacer 170 may be removed along with the mold sacrificial layer 112. That is, it is possible to limit and/or prevent the defect in which the bottom surface of the contact spacer 170 is not removed. Accordingly, contact failure between the gate electrode 120 and the word line contact 160 can be limited and/or prevented, thereby improving reliability of the semiconductor memory device.

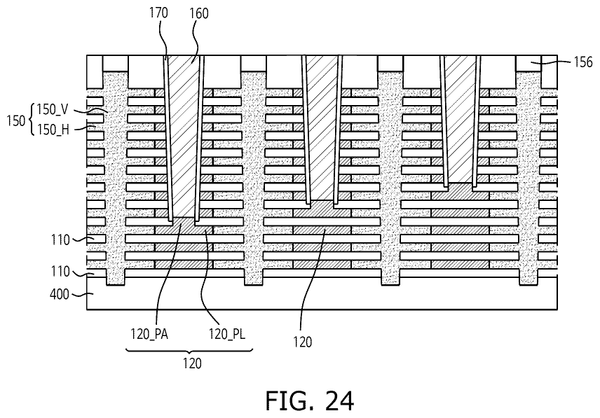

Referring to FIG. 24, the word line contact 160 may be formed on the gate electrode 120 and the contact spacer 170. The word line contact 160 may fill a space inside the contact spacer 170. An end portion of the word line contact 160 may be in contact with the pad part 120_PA.

Although not illustrated, the word line contact 160 may include a contact barrier layer and a contact filling layer. The description of the contact barrier layer and the contact filling layer may be the same as that described in FIG. 5.

Then, referring to FIGS. 3 and 24, the word line via 166 and the cell wiring structure 180 may be formed on the word line contact 160, and the common source plate 105 and the cell substrate 100 may be formed on the support structure 150 so as to form the cell structure CELL. The cell structure CELL may be bonded to the peripheral structure PERI.

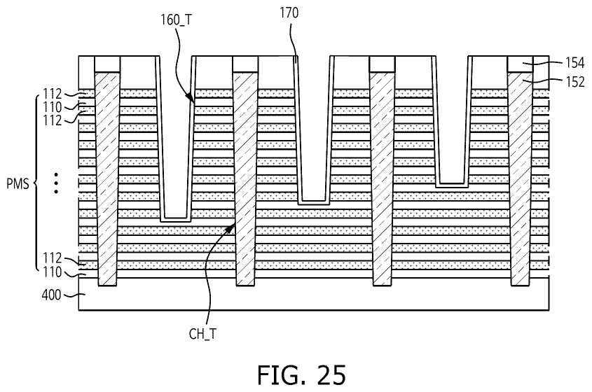

FIGS. 25 to 29 are diagrams showing intermediate stages, provided to explain a method for manufacturing a semiconductor memory device according to some example embodiments of the present disclosure.

Referring to FIG. 25, the pre-stack structure PMS may be formed on the pre-substrate 400. The pre-stack structure PMS may include the plurality of mold insulating layers 110 and mold sacrificial layers 112 that are alternately stacked on each other.

The dummy channel trench CH_T may be formed in the pre-stack structure PMS. The first sacrificial layer 152 may be filled in the dummy channel trench CH_T. The first capping layer 154 may be formed on the first sacrificial layer 152.

The word line contact trench 160_T may be formed in the pre-stack structure PMS. The word line contact trench 160_T may pass through a portion of the pre-stack structure PMS. In some example embodiments, the bottom surface of the word line contact trench 160_T may expose the mold insulating layer 110. The contact spacer 170 may be formed on the sidewall and the bottom surface of the word line contact trench 160_T.

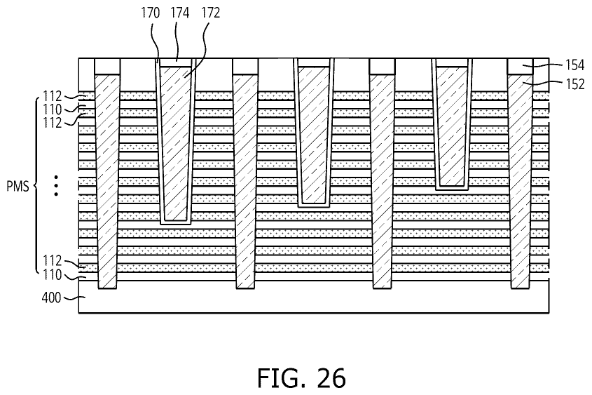

Referring to FIGS. 25 and 26, the second sacrificial layer 172 and the second capping layer 174 may be formed on the contact spacer 170. For example, the second sacrificial layer 172 may be formed in a space in the contact spacer 170. The second capping layer 174 may be formed on the second sacrificial layer 172.

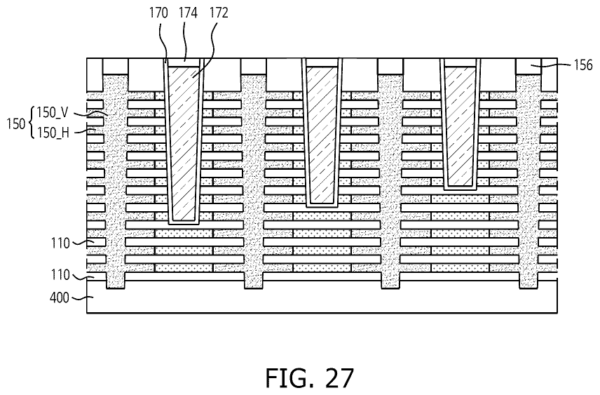

Referring to FIGS. 26 and 27, a portion of the first sacrificial layer 152 and the mold sacrificial layer 112 may be removed, and the support structure 150 may be formed.

For example, the first capping layer 154 and the first sacrificial layer 152 may be removed. The first sacrificial layer 152 may be removed, and a portion of the mold sacrificial layer 112 may be removed.

The support structure 150 may be formed in a portion from which the first sacrificial layer 152 and the mold sacrificial layer 112 were removed. The support structure 150 may include the vertical part 150_V that extends vertically, and the horizontal part 150_H that extends horizontally. The third capping layer 156 may be formed on the support structure 150.

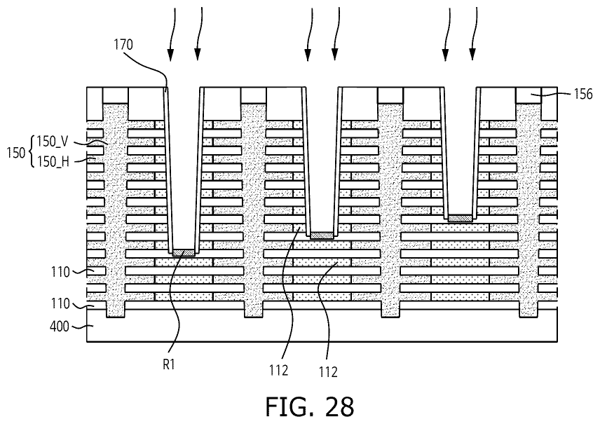

Referring to FIGS. 27 and 28, the second capping layer 174 and the second sacrificial layer 172 may be removed to expose the contact spacer 170. The ion implantation process may be performed on the exposed contact spacer to form the ion implantation region R1. The description of the ion implantation process and the ion implantation region R1 may be the same as that described in FIG. 19.

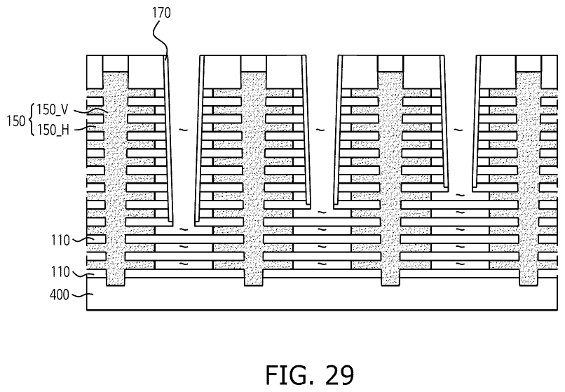

Referring to FIGS. 28 and 29, the mold sacrificial layer 112 and the ion implantation region R1 may be removed. With the removal of the ion implantation region R1, a space from which the mold sacrificial layer 112 was removed and a space inside the contact spacer 170 may be connected to each other.

The gate electrode 120 may be formed between the mold insulating layers 110, and the word line contact 160 may be formed inside the contact spacer 170. The gate electrode 120 and the word line contact 160 may be unitarily formed. For example, the word line contact 160 and the gate electrode 120 may be formed in the same process. That is, the boundary surface between the word line contact 160 and the gate electrode 120 may not be distinguished from each other. The shape of the word line contact 160 and the gate electrode 120 may be the same as that described above with reference to FIGS. 13 and 14.

FIG. 30 is a block diagram provided as an example to explain an electronic system according to some example embodiments of the present disclosure.

Referring to FIG. 30, an electronic system 1000 may include a semiconductor memory device 1100 described above with reference to FIGS. 1 to 17, and a controller 1200 electrically connected to the semiconductor memory device 1100. The electronic system 1000 may be a storage device including one or a plurality of semiconductor memory devices 1100 or an electronic device including the storage device. For example, the electronic system 1000 may be a solid state drive device (SSD), a universal serial bus (USB), a computing system, a medical device, or a communication device, which may include one or a plurality of semiconductor memory devices 1100.

For example, the semiconductor memory device 1100 may be the NAND flash memory device described above with reference to FIGS. 1 to 17. The semiconductor memory device 1100 may include a first structure 1100F and a second structure 1100S on the first structure 1100F. The first structure 1100F may be a peripheral circuit structure including a decoder circuit 1110, the page buffer 1120, and the logic circuit 1130. The second structure 1100S may be a memory cell structure including a bit line BL, a common source line CSL, word lines WL, first and second gate upper lines UL1 and UL2, first and second gate lower lines LL1 and LL2, and memory cell strings CSTR between the bit line BL and the common source line CSL.

In the second structure 1100S, each of the memory cell strings CSTR may include lower transistors LT1 and LT2 adjacent to the common source line CSL and upper transistors UT1 and UT2 adjacent to the bit line BL, and a plurality of memory cell transistors MCT disposed between the lower transistors LT1 and LT2 and the upper transistors UT1 and UT2. The number of the lower transistors LT1 and LT2 and the number of the upper transistors UT1 and UT2 may be modified according to various aspects.

In some example embodiments, the upper transistors UT1 and UT2 may include a string select transistor, and the lower transistors LT1 and LT2 may include a ground select transistor. The gate lower lines LL1 and LL2 each may be gate electrodes of the lower transistors LT1 and LT2. The word lines WL may be gate electrodes of the memory cell transistors MCT, and the gate upper lines UL1 and UL2 may be gate electrodes of the upper transistors UT1 and UT2, respectively.

The common source line CSL, the first and second gate lower lines LL1 and LL2, the word lines WL, and the first and second gate upper lines UL1 and UL2 may be electrically connected to the decoder circuit 1110 through first connection lines 1115 extending from within the first structure 1100F and to the second structure 1100S. The bit lines BL may be electrically connected to the page buffer 1120 through second connection wires 1125 extending from within the first structure 1100F and to the second structure 1100S.

In the first structure 1100F, the decoder circuit 1110 and the page buffer 1120 may perform a control operation on at least one memory cell transistor selected from among the plurality of memory cell transistors MCT. The decoder circuit 1110 and the page buffer 1120 may be controlled by the logic circuit 1130. The semiconductor memory device 1100 may communicate with the controller 1200 through the input and output pad 1101 electrically connected to the logic circuit 1130. The input and output pad 1101 may be electrically connected to the logic circuit 1130 through an input and output connection wiring 1135 extending from within the first structure 1100F and to the second structure 1100S.

The controller 1200 may include a processor 1210, a NAND controller 1220, and a host interface 1230. According to some example embodiments, the electronic system 1000 may include a plurality of semiconductor memory devices 1100, and in some example embodiments, the controller 1200 may control the plurality of semiconductor memory devices 1100.

The processor 1210 may control the overall operation of the electronic system 1000 including the controller 1200. The processor 1210 may operate according to desired (and/or alternatively predetermined) firmware, and may control the NAND controller 1220 to access the semiconductor memory device 1100. The NAND controller 1220 may include a NAND interface 1221 that processes communication with the semiconductor memory device 1100. A control command for controlling the semiconductor memory device 1100, data to be written in the memory cell transistors MCT of the semiconductor memory device 1100, data to be read from the memory cell transistors MCT of the semiconductor memory device 1100, etc. may be transmitted through the NAND interface 1221. The host interface 1230 may provide a function of communication between the electronic system 1000 and an external host. Upon receiving a control command from the external host through the host interface 1230, the processor 1210 may control the semiconductor memory device 1100 in response to the control command.

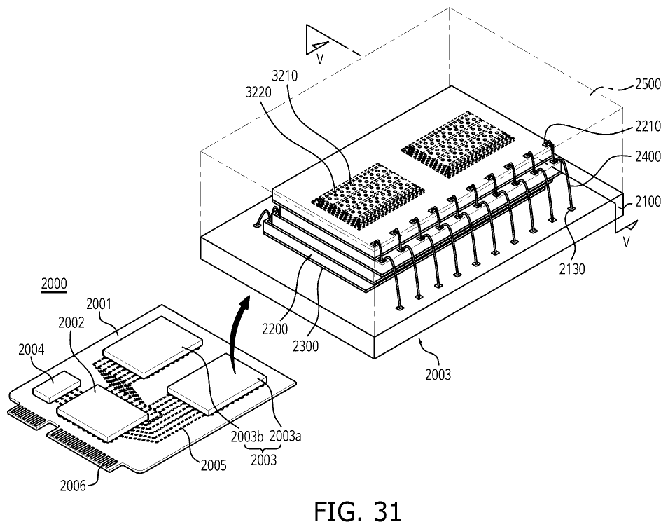

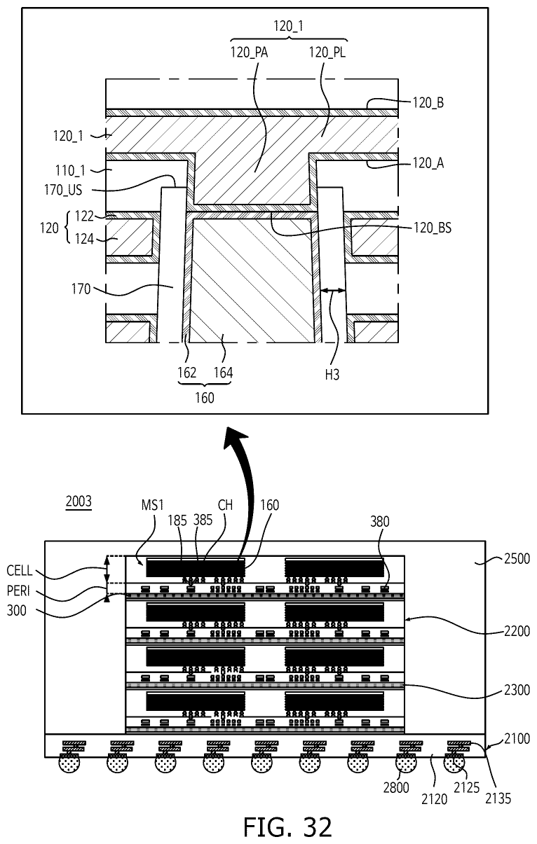

FIG. 31 is an example perspective view illustrating an electronic system including a semiconductor memory device according to some example embodiments of the present disclosure. FIG. 32 is a schematic cross-sectional view taken along line V-V of FIG. 31.

Referring to FIG. 31, an electronic system 2000 may include a main substrate 2001, a controller 2002 mounted on the main substrate 2001, one or more semiconductor packages 2003, and a DRAM 2004. The semiconductor package 2003 and the DRAM 2004 may be connected to the controller 2002 by wiring patterns 2005 formed on the main substrate 2001.

The main substrate 2001 may include a connector 2006 including a plurality of pins coupled to the external host. The number and arrangement of the plurality of pins in the connector 2006 may vary according to a communication interface between the electronic system 2000 and the external host. In some example embodiments, the electronic system 2000 may communicate with an external host according to any one of interfaces such as Universal Serial Bus (USB), Peripheral Component Interconnect Express (PCI-Express), Serial Advanced Technology Attachment (SATA), and M-Phy for Universal Flash Storage (UFS). In some example embodiments, the electronic system 2000 may operate by the power supplied from an external host through the connector 2006. The electronic system 2000 may further include a Power Management Integrated Circuit (PMIC) that distributes the power supplied from the external host to the controller 2002 and the semiconductor package 2003.

The main controller 2002 may record data in the semiconductor package 2003 or read data from the semiconductor package 2003, and may improve the operation speed of the electronic system 2000.

The DRAM 2004 may be a buffer memory to alleviate the speed difference between the external host and the semiconductor package 2003 that is a data storage space. The DRAM 2004 included in the electronic system 2000 may also operate as a kind of cache memory, and may also provide a space for temporarily storing data in a control operation for the semiconductor package 2003. If the electronic system 2000 includes the DRAM 2004, in addition to the NAND controller for controlling the semiconductor package 2003, the main controller 2002 may further include a DRAM controller for controlling the DRAM 2004.

The semiconductor package 2003 may include first and second semiconductor packages 2003a and 2003b spaced apart from each other. Each of the first and second semiconductor packages 2003a and 2003b may be a semiconductor package including a plurality of semiconductor chips 2200. Each of the first and second semiconductor packages 2003a and 2003b may include a package substrate 2100, semiconductor chips 2200 on the package substrate 2100, adhesive layers 2300 disposed on a lower surface of each of the semiconductor chips 2200, a connection structure 2400 electrically connecting the semiconductor chips 2200 and the package substrate 2100, and a molding layer 2500 covering the semiconductor chips 2200 and the connection structure 2400 on the package substrate 2100.

The package substrate 2100 may be a printed circuit board including package upper pads 2130. Each of the semiconductor chips 2200 may include an input and output pad 2210. The input and output pad 2210 may correspond to the input and output pad 1101 of FIG. 30. Each of the semiconductor chips 2200 may include metal lines 3210 and channel structures 3220. Each of the semiconductor chips 2200 may include the semiconductor memory device described above with reference to FIGS. 1 to 17.

In some example embodiments, the connection structure 2400 may be a bonding wire electrically connecting the input and output pad 2210 to the package upper pads 2130. Therefore, in each of the first and second semiconductor packages 2003a and 2003b, the semiconductor chips 2200 may be electrically connected to each other with the bonding wire method, and may be electrically connected to the package upper pads 2130 of the package substrate 2100. In some example embodiments, in each of the first and second semiconductor packages 2003a and 2003b, the semiconductor chips 2200 may be electrically connected to each other through a connection structure including through-electrodes (Through Silicon Via, TSV) instead of the bonding wire type connection structure 2400.

In some example embodiments, the main controller 2002 and the semiconductor chips 2200 may be included in one package. In some example embodiments, the main controller 2002 and the semiconductor chips 2200 may be mounted on a separate interposer substrate different from the main substrate 2001, and the main controller 2002 and the semiconductor chips 2200 may be connected to each other through wiring formed on the interposer substrate.

In some example embodiments, the package substrate 2100 may be a printed circuit board. The package substrate 2100 may include a package substrate body portion 2120, the package upper pads 2130 disposed on the upper surface of the package substrate body portion 2120, lower pads 2125 disposed on the lower surface of the package substrate body portion 2120 or exposed through the lower surface, and internal wires 2135 electrically connecting the upper pads 2130 and the lower pads 2125 inside the package substrate body portion 2120. The upper pads 2130 may be electrically connected to the connection structures 2400. The lower pads 2125 may be connected to the wiring patterns 2005 of the main substrate 2001 of the electronic system 2000 through conductive connections 2800, as illustrated in FIG. 31.

In an electronic system according to some example embodiments, each of the semiconductor chips 2200 may include the semiconductor memory device described above with reference to FIGS. 1 to 17. For example, each of the semiconductor chips 2200 may include a peripheral circuit structure PERI and a cell structure CELL stacked on the peripheral circuit structure PERI. For example, the peripheral circuit structure PERI may include the peripheral circuit substrate 300 and the peripheral circuit wiring structure 380 described above with reference to FIGS. 1 to 17. For example, the cell structure CELL may include the cell substrate 100, the first mold structure MS1, the channel structure CH, the bit line BL, the word line contact 160, and the contact spacer 170 described above with reference to FIGS. 1 to 17. The peripheral circuit structure PERI and the cell structure CELL may be bonded to each other through the first bonding metal 185 and the second bonding metal 385.

One or more of the elements disclosed above may include or be implemented in processing circuitry such as hardware including logic circuits; a hardware/software combination such as a processor executing software; or a combination thereof. For example, the processing circuitry may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, an application-specific integrated circuit (ASIC), etc.

Although some example embodiments of the present disclosure have been described with reference to the accompanying drawings, those of ordinary skill in the art to which the present disclosure pertains will understand that the present disclosure may be implemented in other specific forms without changing its technical idea or essential features. Therefore, it should be understood that the some example embodiments described above are illustrative and non-limiting in all respects.

1. A semiconductor memory device, comprising:
a substrate;
a mold structure including a plurality of mold insulating layers and a plurality of gate electrodes alternately stacked on each other on the substrate in a first direction;
a channel structure passing through the mold structure and extending in the first direction;
a word line contact passing through a portion of the mold structure and extending in the first direction; and
a contact spacer surrounding a side surface of the word line contact,
wherein the plurality of gate electrodes include a first gate electrode electrically connected to the word line contact,
the first gate electrode includes a plate part extending in a second direction perpendicular to the first direction, and a pad part protruding from the plate part toward the word line contact, and
one surface of the pad part is in contact with the word line contact.

2. The semiconductor memory device according to claim 1, wherein the plate part includes a first surface and a second surface opposite the first surface,
the pad part protrudes from the first surface of the plate part toward the word line contact,
the plurality of mold insulating layers include a first mold insulating layer on the first surface of the plate part, and
at least a portion of the pad part is in the first mold insulating layer.

3. The semiconductor memory device according to claim 2, wherein a distance from the first surface of the plate part to an end portion of the contact spacer is different than a distance from the first surface of the plate part to the one surface of the pad part.

4. The semiconductor memory device according to claim 2, wherein an end portion of the contact spacer is in the first mold insulating layer.

5. The semiconductor memory device according to claim 1, wherein a thickness of the pad part in the first direction is greater than a thickness of the contact spacer in the second direction.

6. The semiconductor memory device according to claim 1, wherein the first gate electrode includes an electrode barrier layer, and an electrode filling layer in the electrode barrier layer,
the word line contact includes a contact barrier layer, and a contact filling layer in the contact barrier layer, and
the electrode barrier layer and the contact barrier layer are in contact with each other.

7. The semiconductor memory device according to claim 1, wherein the word line contact passes through one or more gate electrodes disposed on one side of the first gate electrode of the plurality of gate electrodes.

8. The semiconductor memory device according to claim 1, further comprising support structures around the word line contact,
wherein the support structures include a vertical part passing through the mold structure, and a horizontal part extending in a direction parallel to a lower surface of the substrate, and
the horizontal part is at a same level as the first gate electrode.

9. The semiconductor memory device according to claim 1, wherein the one surface of the pad part has a convex shape curved outward toward the word line contact.

10. The semiconductor memory device according to claim 1, wherein the one surface of the pad part has a concave shape curved inward from the word line contact.

11. The semiconductor memory device according to claim 1, wherein a diameter of the pad part in the second direction progressively decreases from the plate part toward the word line contact.

12. The semiconductor memory device according to claim 1, wherein a side surface of the pad part includes a rounding part, and
the rounding part is in contact with the contact spacer.

13. The semiconductor memory device according to claim 1, wherein the plate part includes a first surface and a second surface opposite the first surface,
the pad part protrudes from the first surface of the plate part toward the word line contact, and
a distance from the second surface of the plate part to the first surface of the plate part is equal to or greater than a distance from the second surface of the plate part to an end portion of the contact spacer.

14. The semiconductor memory device according to claim 1, wherein the plate part includes a first surface and a second surface opposite the first surface,
the pad part protrudes from the first surface of the plate part toward the word line contact, and
an end portion of the contact spacer passes through the first surface of the plate part.

15. The semiconductor memory device according to claim 1, wherein the first gate electrode and the word line contact are unitary without a boundary surface therebetween.

16. A semiconductor memory device comprising:
a peripheral circuit structure; and
a cell structure stacked on the peripheral circuit structure,
wherein the cell structure includes
a substrate including a cell array region and an extension region, wherein the substrate includes a first substrate surface opposite the peripheral circuit structure and a second substrate surface opposite the first substrate surface,
a mold structure including a plurality of mold insulating layers and a plurality of gate electrodes alternately stacked on each other on the first substrate surface of the substrate in a first direction,
a channel structure in the cell array region, the channel structure passing through the mold structure and extending in the first direction,
a word line contact in the extension region, the word line contact passing through a portion of the mold structure and extending in the first direction, and
a contact spacer surrounding a side surface of the word line contact,
wherein the plurality of gate electrodes include a first gate electrode electrically connected to the word line contact,
the first gate electrode includes a plate part extending in a second direction perpendicular to the first direction, and a pad part protruding from the plate part toward the word line contact, and
at least a portion of the pad part overlaps the contact spacer in the second direction.

17. The semiconductor memory device according to claim 16, wherein the plate part includes a first plate surface and a second plate surface opposite the first plate surface,
the pad part protrudes from the first plate surface of the plate part toward the word line contact,
a distance from the first plate surface of the plate part to an end portion of the contact spacer is less than a distance from the first plate surface of the plate part to one surface of the pad part.

18. The semiconductor memory device according to claim 16, further comprising a bit line connected to the channel structure,
wherein the word line contact passes through one or more gate electrodes from among the plurality of gate electrodes that are between the first gate electrode and the bit line.

19. The semiconductor memory device according to claim 18, further comprising a cell wiring structure bonded between the bit line and the peripheral circuit structure, and between the word line contact and the peripheral circuit structure.

20. An electronic system, comprising:
a main substrate;
a semiconductor memory device on the main substrate, the semiconductor memory device including a peripheral circuit structure and a cell structure stacked on the peripheral circuit structure; and
a controller on the main substrate, the controller being electrically connected to the semiconductor memory device,
wherein the cell structure includes
a substrate including a cell array region and an extension region, wherein the substrate includes a first surface opposite the peripheral circuit structure and a second surface opposite the first surface,
a mold structure including a plurality of mold insulating layers and a plurality of gate electrodes alternately stacked on each other on the first surface of the substrate in a first direction,
a channel structure in the cell array region, the channel structure passing through the mold structure and extending in the first direction,
a word line contact in the extension region, the word line contact passing through a portion of the mold structure and extending in the first direction, and
a contact spacer surrounding a side surface of the word line contact,
wherein the plurality of gate electrodes include a first gate electrode electrically connected to the word line contact,
the first gate electrode includes a plate part extending in a second direction perpendicular to the first direction, and a pad part protruding from the plate part toward the word line contact, and
one surface of the pad part is in contact with the word line contact.
